(19) United States
(12) Patent Application Publication
(10) Pub. No.: US 2015/0069555 A1
(43) Pub. Date: Mar. 12, 2015

(54) MAGNETIC MEMORY

(71) Applicants: Shintaro SAKAI, Seoul (KR); Masahiko NAKAYAMA, Seoul (KR)

(72) Inventors: Shintaro SAKAI, Seoul (KR); Masahiko NAKAYAMA, Seoul (KR)

(21) Appl. No.: 14/201,719

(22) Filed: Mar. 7, 2014

Related U.S. Application Data
(60) Provisional application No. 61/875,431, filed on Sep. 9, 2013.

(51) Int. Cl. H01L 27/22; H01L 43/02

(52) U.S. Cl. CPC H01L 27/222; H01L 43/02
USPC 257/421

(57) ABSTRACT

According to one embodiment, a magnetic memory includes first and second magnetoresistive effect elements neighboring in a first direction in a cell array of a substrate, each of the first and second magnetoresistive effect elements including a first magnetic layer with an invariable direction of magnetization, a second magnetic layer with a variable direction of magnetization, and a nonmagnetic layer between the first magnetic layer and the second magnetic layer. Directions of magnetization of the first magnetic layers of the first and second magnetoresistive effect elements are different from each other.

### CROSS-REFERENCE TO RELATED APPLICATIONS

This application claims the benefit of U.S. Provisional Application No. 61/875,431, filed Sep. 9, 2013, the entire contents of which are incorporated herein by reference.

### FIELD

Embodiments described herein relate generally to a magnetic memory.

### BACKGROUND

In recent years, a spin transfer torque-type magnetoresistive random access memory (STT-MRAM) has been proposed as one of semiconductor memories. In the MRAM, a magnetoresistive effect element is included in a memory cell. The magnetoresistive effect element includes two magnetic layers (ferromagnetic layers) and a nonmagnetic layer which is provided between the two magnetic layers. Depending on the magnetization states of the two magnetic layers of the magnetoresistive effect element, that is, depending on whether the spin directions of the two magnetic layers are parallel or antiparallel, “1” or “0” information is stored in the memory cell.

### BRIEF DESCRIPTION OF THE DRAWINGS

FIG. 1 is a view illustrating the whole structure of a magnetic memory;

FIG. 2 is a view illustrating a layout example of a vicinity of a cell array of the magnetic memory;

FIG. 3 is an equivalent circuit diagram illustrating a circuit structure example of the cell array of the magnetic memory;

FIG. 4 is a view which schematically illustrates a structure example of a memory cell of the magnetic memory;

FIG. 5 is a view illustrating a structure example of a magnetoresistive effect element of the magnetic memory;

FIG. 6 is a view illustrating a structure example of the magnetoresistive effect element of the magnetic memory;

FIG. 7 is a schematic view for describing a structure example of a cell array of a magnetic memory according to a first embodiment;

FIG. 8 is a top view illustrating a structure example of the cell array of the magnetic memory of the first embodiment;

FIG. 9 is a cross-sectional view illustrating a structure example of the cell array of the magnetic memory of the first embodiment;

FIG. 10 is a schematic view illustrating a structure example of the cell array of the magnetic memory of the first embodiment;

FIG. 11 is a top view illustrating a structure example of the cell array of the magnetic memory of the first embodiment;

FIG. 12 is a cross-sectional view illustrating a structure example of the cell array of the magnetic memory of the first embodiment;

FIG. 13 is a view for explaining an interference between magnetoresistive effect elements;

FIG. 14 is a schematic view for describing a structure example of a cell array of a magnetic memory according to a second embodiment;

FIG. 15 is a schematic view for describing a structure example of the cell array of the magnetic memory of the second embodiment;

FIG. 16 is a schematic view for describing a structure example of a cell array of a magnetic memory according to a third embodiment;

FIG. 17 is a top view illustrating a structure example of the cell array of the magnetic memory of the third embodiment;

FIG. 18 is a cross-sectional view illustrating a structure example of the cell array of the magnetic memory of the third embodiment;

FIG. 19 is a schematic view for describing a manufacturing method of the magnetic memory of the third embodiment;

FIG. 20 is a schematic view illustrating a modification of the magnetic memory of the embodiment;

FIG. 21 is a schematic view illustrating a modification of the magnetic memory of the embodiment; and

FIG. 22 is a schematic view illustrating a modification of the magnetic memory of the embodiment.

### DETAILED DESCRIPTION

Various embodiments will be described hereinafter in detail with reference to the accompanying drawings. In the description below, elements having the same functions and structures are denoted by like reference numerals, and an overlapping description will be given where necessary.

In general, according to one embodiment, a magnetic memory includes a cell array on a substrate; and one or more first magnetoresistive effect elements and one or more second magnetoresistive effect elements, which are provided in the cell array, each of the first and second magnetoresistive effect elements including a first magnetic layer with an invariable direction of magnetization, a second magnetic layer with a variable direction of magnetization, and a nonmagnetic layer between the first magnetic layer and the second magnetic layer, wherein at least one of the first magnetoresistive effect elements neighbors at least one of the second magnetoresistive effect elements in a first direction, and directions of magnetization of the first magnetic layers of the first and second magnetoresistive effect elements, which neighbor in the first direction, are different from each other.

### EMBODIMENTS

### (1) First Embodiment

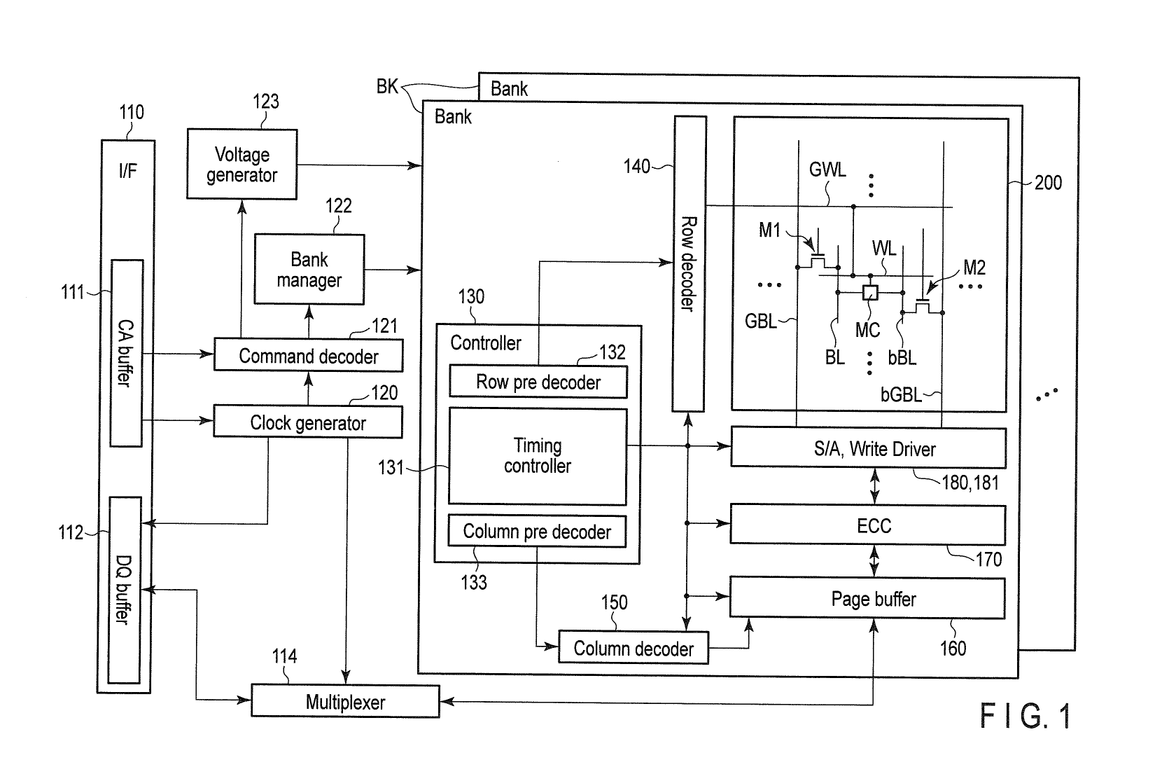

Referring to FIG. 1 to FIG. 11, a magnetic memory according to a first embodiment will be described.

The structure of the magnetic memory according to the first embodiment is described with reference to FIG. 1 to FIG. 6.

FIG. 1 is a block diagram illustrating an example of the whole structure of the magnetic memory of the embodiment.

As illustrated in FIG. 1, the magnetic memory of the embodiment includes a cell array 200 and a plurality of circuits for controlling the operation of the cell array 200.

In the magnetic memory, magnetoresistive effect elements are used as memory elements in the cell array 200. The magnetic memory of the embodiment is, for example, a magnetoresistive random access memory (MRAM).

The MRAM of the embodiment includes an interface circuit 110 for transmission/reception of data and transmission/reception of a control signal (command/status) between an MRAM (e.g. an MRAM package) and an external device (e.g. a memory controller or a host device). A CA buffer 111 and a DQ buffer 112 are provided in the interface circuit 110.

The CA buffer 111 receives, for example, a command/address signal, a clock enable signal, a bank select signal, and an external clock signal from the external device. The DQ buffer 112 transmits or receives a data input/output signal (data), a data strobe signal and a data mask signal.

A clock generator 120 generates an internal clock of the MRAM, based on a signal from the CA buffer 111 based on the clock enable signal. The generated internal clock is supplied to predetermined circuits in the MRAM, such as a command decoder 121, a multiplexer 114 and the DQ buffer 112. The respective circuits in the MRAM operate at an operation timing based on the internal clock generated by the clock generator 121.

The command decoder 121 decodes a command based on the command/address signal which is transferred from the CA buffer 111. The decoded command is sent to a bank manager 122 and a voltage generator 123.

In order to execute an operation corresponding to the command/address signal, the bank manager 122 transfers various information, such as addresses in the cell array 200, and control signals to respective circuits in a bank BK, to a bank BK which is selected by a bank select signal.

The voltage generator 123 generates various voltages which are used for an operation corresponding to a command, and supplies the generated voltages to predetermined circuits in the bank BK.

For example, a plurality of banks BK are provided in the MRAM.

The cell array 200 is provided in the bank BK. Global bit lines GBL and bGBL, bit lines BL and bBL, a global word line GWL and word lines WL are provided in the cell array 200. In the cell array 200, a plurality of memory cells MC are provided such that the memory cells MC are connected to these lines GBL, bGBL, BL, bBL, GWL and WL.

A controller 130 is provided in the bank BK. The controller 130 controls the operation of each circuit in the bank BK. The controller 130 includes a timing controller 131, a row pre-decoder 132 and a column pre-decoder 133 and the like.

The timing controller 131 controls operation timings of respective circuits 140, 150, 160, 170, 180 and 181 in the bank BK.

The row pre-decoder 132 executes, for example, pre-decode relating to a row address of an address signal from the bank manager 122. The column pre-decoder 133 executes, for example, pre-decode relating to a column address of an address signal from the bank manager 122.

A row decoder 140 decodes a row address from the row pre-decoder 132. Based on the decoded row address, the row decoder 140 controls activation of the global word line GWL and word lines (also referred to as “sub-word lines” or “local word lines”) WL in the cell array 200.

A column decoder 150 decodes a column address from the column pre-decoder 133. Based on the decoded column address, the column decoder 150 controls activation of the global bit lines GBL and bGBL and bit lines (also referred to as “sub-bit lines” or “local bit lines”) BL and bBL in the cell array 200.

The memory cells MC in the cell array 200 are accessed by the row decoder 140 and column decoder 150.

A read circuit (sense amplifier circuit) 180 and a write circuit (write driver) 181 are driven at a time of data read and data write from/to the cell array 200.

The read circuit 180 is driven at a time of data read, under the control of the controller 130. The read circuit 180 supplies a read current (or read voltage) to a memory cell MC in the cell array 200, which has been selected based on an address signal, via the global bit lines GBL and bGBL and bit lines BL and bBL. The read circuit 180 reads data which is stored in the memory cell MC, by sensing a current value of a read current or a potential of the bit line.

The write circuit 181 is driven at time of data write, under the control of the controller 130. The write circuit 181 supplies a write current to a memory cell in the cell array 200, which has been selected based on an address, via the global bit lines GBL and bGBL and bit lines BL and bBL.

For example, when data write of the MRAM is executed by a write method based on spin-transfer torque (STT), the write current flows in a magnetoresistive effect element in the memory cell. In an STT-MRAM, the direction of a write current flowing in the magnetoresistive effect element is controlled in accordance with data (for example, “0” or “1”) that is to be written in the memory cell.

An error checking and correcting (ECC) circuit 170 executes an ECC process on data that is to be written in the cell array 200 and data that has been read from the cell array 200.

A page buffer 160 temporarily stores data that is to be written in the cell array 200 and data that has been read from the cell array 200, in units of data (data size) called “page”.

The multiplexer 114 adjusts a transfer timing of data between the bank BK and the buffer 112 (or the MRAM and the external device) by a timing based on the internal clock.

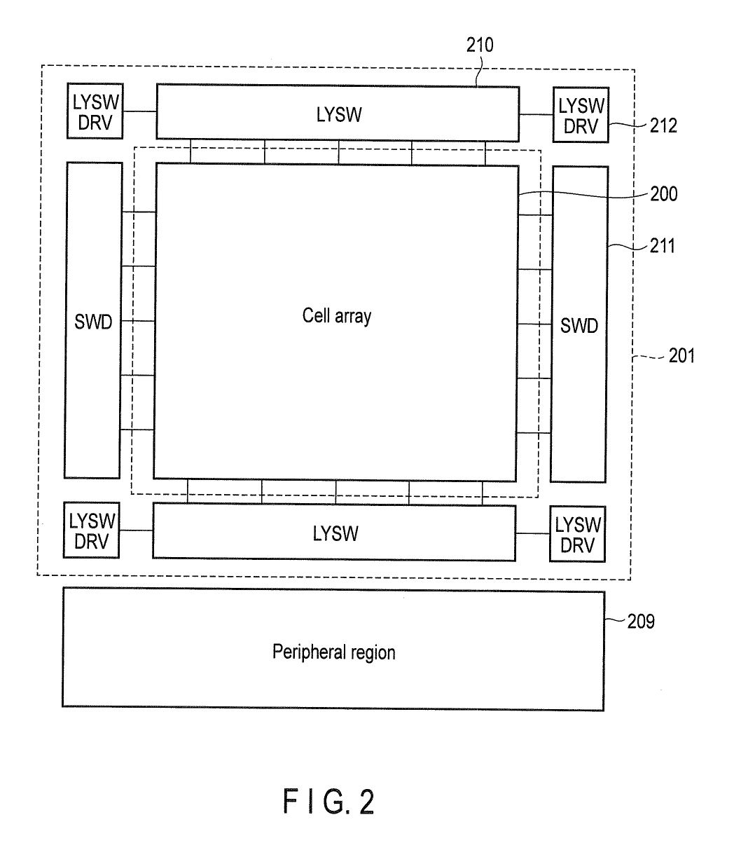

FIG. 2 is a view illustrating an example of a circuit layout of a vicinity of the cell array of the MRAM.

As illustrated in FIG. 2, in the MRAM, a core circuit 201 and a peripheral circuit 209 are provided in the vicinity of the cell array 200.

In the cell array 200, a plurality of memory cells are arranged in a matrix. Data is stored in each memory cell.

The core circuit 201 is electrically connected to the cell array 200. Data is input/output between the core circuit 201 and the cell array 200. The core circuit 201 includes a local column switch circuit 210, a sub-word line decoder 211, and a local column switch driver 212.

The local column switch circuit 210 selectively connects the bit line BL, bBL and the global bit line in accordance with a column address in a magnetic memory in which a hierarchical bit line scheme is adopted. In accordance with a row address, the sub-word line decoder 211 activates a word line, and selectively connects the word line and the global word line. The local column switch driver 212 controls ON/OFF of local column switches (for example, transistors M1 and M2 in FIG. 1) in the local column switch circuit 210.

For example, the local column switch circuit 210 includes a transistor with a buried gate electrode, the sub-word line decoder 211 includes a transistor with a planar-type gate electrode, and the local column switch driver 212 includes both the buried gate-type transistor and the planar-type transistor.

The peripheral circuit (a peripheral circuit group, a peripheral circuit region) 209 is electrically connected to the cell array 200 via the core circuit 201. The peripheral circuit 209 includes, for example, a control circuit which controls the core circuit 201 and cell array 200, the read circuit (read driver) 180 and the write circuit (write driver) 181 and the like. The peripheral circuit mainly includes planar-type transistors.

The cell array 200, core circuit 201 and peripheral circuit 209 are formed on the same semiconductor substrate. The core circuit 201 and peripheral circuit 209 neighbor the cell array 200. Incidentally, a plurality of cell arrays 200 and a plurality of core circuits 201 may be provided in one semiconductor substrate. In this case, for example, one peripheral circuit (peripheral circuit region) is provided in the semiconductor substrate such that the peripheral circuit is shared by the plural cell arrays 200 and plural core circuits 201.

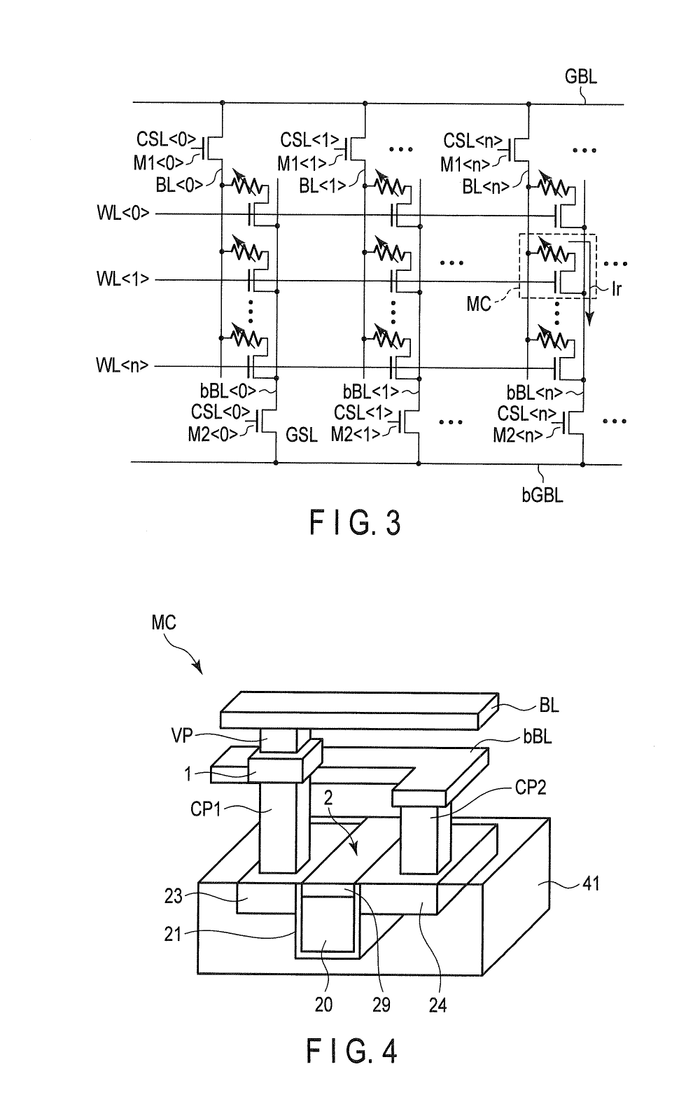

FIG. 3 is an equivalent circuit diagram illustrating an example of an internal structure of the cell array of the MRAM.

As illustrated in FIG. 3, the cell array 200 includes a plurality of memory cells MC.

In the cell array 200, there are provided a plurality of bit lines (sub-bit lines/local bit lines) BL<0>, BL<1>, BL<n>, bBL<0>, bBL<1>, and bBL<n>, and a plurality of word lines (sub-word lines/local word lines) WL<0>, WL<1> and WL<n>. In the description below, when the bit lines BL<0>, BL<1> and BL<n> are not distinguished, these bit lines are referred to as “bit lines BL”. When the bit lines bBL<0>, bBL<1> and bBL<n> are not distinguished, these bit lines are referred to as “bit lines bBL”. When the plural word lines WL<0>, WL<1> and WL<n> are not distinguished, these word lines are referred to as “word lines WL”.

The bit lines BL and bBL extend in a column direction, and the word lines WL extend in a row direction. Two bit lines BL and bBL form one bit line pair.

The memory cell MC is connected to the bit lines BL and bBL and word line WL.

A plurality of memory cells MC, which are arranged in the column direction, are connected to one bit line pair BL, bBL. A plurality of memory cells MC, which are arranged in the row direction, are connected to a common word line WL.

In the hierarchical bit line scheme, plural bit lines BL<0>, BL<1> and BL<n> are connected to one global bit line GBL via local column switches M1<0>, M1<1> and M1<n>, and plural bit lines bBL<0>, bBL<1> and bBL<n> are connected to the other global bit line bGBL via local column switches M2<0>, M2<1> and M2<n>.

ON/OFF of the local column switches M1<0>, M1<1>, M1<n>, M2<0>, M2<1> and M2<n> are controlled by control signals CSL<0>, CSL<1> and CSL<n>, respectively.

In the description below, when the local column switches M1<0>, M1<1>, M1<n>, M2<0>, M2<1> and M2<n> are not distinguished, these switches are referred to as “local column switches M1, M2”.

For example, in the hierarchical word line scheme, plural word lines WL are connected to the global word line GWL via a sub-word line driver or local row switch (not shown).

The memory cell MC includes, for example, one magnetoresistive effect element 1 as a memory element, and one select switch 2. The select switch 2 is a field-effect transistor (e.g. n-channel MOS transistor). In the description below, the field-effect transistor, which functions as the select switch 2 in the memory cell MC, is referred to as “cell transistor (or select transistor) 2”.

One end of the MTJ element 1 is connected to the bit line BL, and the other end of the MTJ element 1 is connected to one end (source/drain) of a current path of the cell transistor 2. The other end (drain/source) of the current path of the cell transistor 2 is connected to the bit line bBL. A control terminal (gate) of the cell transistor 2 is connected to the word line WL.

FIG. 4 is a view illustrating an example of the structure of the memory cell MC of the MRAM.

The cell transistor 2 is provided on a semiconductor substrate 41.

The cell transistor 2 includes a gate electrode 20 which is buried in a recess in the semiconductor substrate 41. A gate insulation film 21 is provided between the semiconductor substrate 41 and the gate electrode 20. In the embodiment, the structure, in which the gate electrode of the transistor is buried in the semiconductor substrate, is referred to as “buried gate structure”.

The gate insulation film 21 is formed on an inner surface of the recess. The gate electrode 20 is formed on the inner surface of the gate insulation film 21 so as to fill a lower side part of the recess. The gate electrode 20 is formed so as to extend in the row direction. The gate electrode 20 is used as the word line WL.

An insulation film 29, which is formed of, e.g. SiN, is provided on upper surfaces of the gate insulation film 21 and gate electrode 20 so as to fill an upper side part of the recess. The upper surface of the insulation film 29 is substantially on a level with the upper surface of the semiconductor substrate 41.

A diffusion layer (hereinafter referred to as “source/drain diffusion layer”) 23, 24, which functions as a source/drain of the cell transistor 2, is formed in a surface of the semiconductor substrate 41 such that the gate insulation film 21, gate electrode 20 and insulation film 29 are interposed between source/drain diffusion layers 23, 24. The source/drain diffusion layer 23, 24 of the cell transistors 2 of two memory cells, which neighbor in the column direction, are shared by the two memory cells which neighbor in the column direction.

In the memory cells arranged in the row direction, the source/drain diffusion layers 23, 24 of each cell transistor 2 are isolated by the device isolation region (device isolation insulation film).

As shown in FIG. 4, contact plugs CP1 and CP2 are provided in an interlayer insulation film (not shown) on the semiconductor substrate 41 such that the contact plugs CP1 and CP2 are connected to the source/drain diffusion layers 23 and 24 of the cell transistor 2.

A magnetoresistive effect element 1 is provided on the contact plug CP1, and the magnetoresistive effect element 1 is connected to the source/drain diffusion layer 23 of the cell transistor 2 via the contact plug CP1. A via-plug VP is provided on the magnetoresistive effect element 1, and the magnetoresistive effect element 1 is connected to a bit line BL via the via-plug VP. A bit line bBL is connected to the source/drain diffusion layer 24 of the cell transistor 2 via the contact plug CP2. Incidentally, the two bit lines BL and bBL, which constitute a bit line pair, may be provided on the same interconnect level.

For example, in the case where the feature size is “F”, the cell size of the memory cell is set to be about 4F² to 6F².

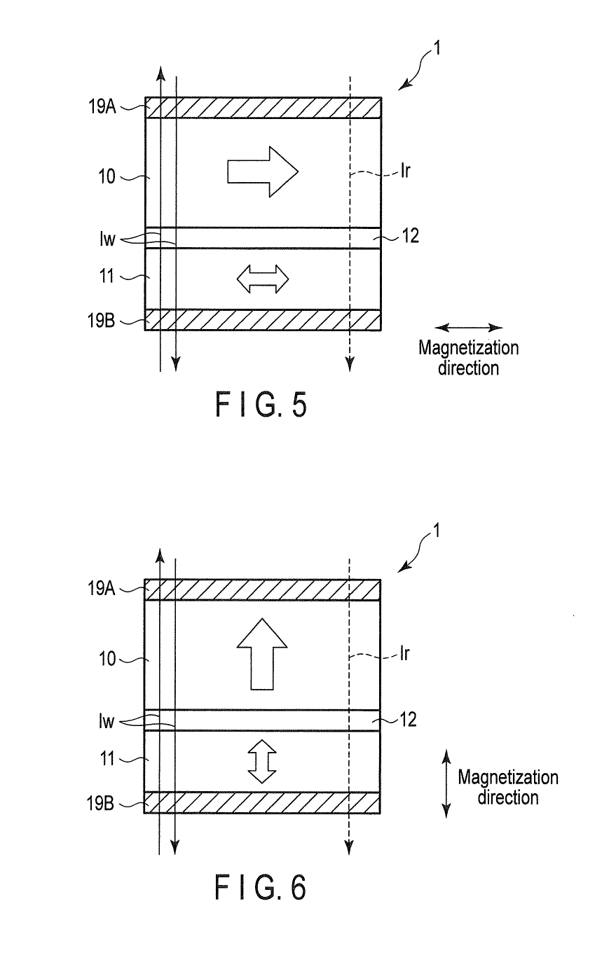

Referring to FIG. 5 and FIG. 6, a description is given of the structure of the magnetoresistive effect element of the MRAM of the embodiment.

FIG. 5 and FIG. 6 are cross-sectional views which schematically illustrate the structure of the magnetoresistive effect element.

The magnetoresistive effect element, which is used for the memory element 1, is an MTJ element including a magnetic tunnel junction.

The MTJ element 1 includes a first magnetic layer 10 having an invariable (fixed) magnetization orientation, a second magnetic layer 11 having a variable magnetization orientation, and a nonmagnetic layer 12 between the two magnetic layers 10 and 11. A multilayer structure including the two magnetic layers 10 and 11 and nonmagnetic layer 12 forms a magnetic tunnel junction. The multilayer structure 10, 11, 12, which forms the magnetic tunnel junction, is provided, for example, between two electrodes 19A and 19B.

In the present embodiment, the magnetic layer 10 having the invariable magnetization orientation is referred to as “reference layer 10”, and the magnetic layer 11 having the variable magnetization orientation is referred to as “storage layer 11”. The reference layer 10 is also called “pin layer” or “pinned layer”. The storage layer 11 is also called “recording layer”, “magnetization free layer” or “free layer”.

FIG. 5 illustrates an MTJ element 1 of an in-plane magnetization type (parallel magnetization type). The in-plane magnetization-type MTJ element 1 has a magnetic anisotropy in a parallel direction to the film surface of the magnetic layer 10, 11. The magnetization orientation of the magnetic layer 10, 11 is parallel to the film surface of the magnetic layer 10, 11. For example, the in-plane magnetization-type MTJ element 1 is formed such that the magnetization orientation of the magnetic layer 10, 11 is made parallel to the film surface of the magnetic layer 10, 11, by the shape magnetic anisotropy of the magnetic material. For example, the in-plane magnetization-type MTJ element 1 has such a plan-view shape that one of two axes, which cross each other in a plane, is longer than the other, and the in-plane magnetization-type MTJ element 1 has a magnetic anisotropy in the major-axis direction. The in-plane magnetization-type MTJ element 1 has, for example, an elliptic plan-view shape.

FIG. 6 illustrates an MTJ element 1 of a vertical magnetization type. In the vertical magnetization-type MTJ element 1, the magnetization orientation of the magnetic layer 10, 11 is substantially perpendicular to the film surface of the magnetic layer 10, 11. The magnetic layer 10, 11 of the vertical magnetization-type MTJ element 1 has a magnetic anisotropy in a substantially perpendicular direction to the surface of the semiconductor substrate. In this context, “substantially perpendicular” means that the residual magnetization direction is in a range of 45°<θ≦90°, relative to the film surface of the magnetic layer.

The vertical magnetization-type MTJ element 1 is formed such that the magnetization orientation of the magnetic layer 10, 11 is made perpendicular to the film surface of the magnetic layer 10, 11, by the magnetocrystalline anisotropy of the magnetic material or interface magnetic anisotropy. For example, the vertical magnetization-type MTJ element 1 has a circular plan-view shape.

At a time of data write, the magnetization orientation of the storage layer 11 of the MTJ element is varied by an STT method. Spin-polarized electrons included in a current Iw, which flows in the element 1 and is not less than a magnetization reversal threshold of the storage layer 11, acts on the magnetization (spin) of the storage layer 11, and thereby the magnetization orientation of the storage layer 11 is varied.

That “the magnetization orientation of the reference layer 10 is invariable” or that “the magnetization orientation of the reference layer 10 is fixed” means that the magnetization orientation of the reference layer 10 does not vary when the current (magnetization reversal current) Iw, which is used for reversing the magnetization orientation of the storage layer 11, has flowed in the reference layer 10. Thus, in the MTJ element 1, a magnetic layer with a high magnetization reversal threshold is used as the reference layer 10, and a magnetic layer with a magnetization reversal threshold, which is lower than the magnetization reversal threshold of the reference layer 10, is used as the storage layer 11. Thereby, the MTJ element 1 including the storage layer 11 with the variable magnetization orientation and the reference layer 10 with the invariable magnetization orientation is formed.

When the magnetization direction of the storage layer 11 and the magnetization orientation of the reference layer 10 are set in a parallel state by the STT method, that is, when the magnetization orientation of the storage layer 11 and the magnetization orientation of the reference layer 10 are set to be identical, a current Iw, which flows from the storage layer 11 toward the reference layer 10, is supplied to the MTJ element 1. In this case, electrons move from the reference layer 10 toward the storage layer 11 via the tunnel barrier layer 12. Of the electrons which have passed through the reference layer 10 and tunnel barrier layer 12, majority electrons (spin-polarized electrons) have the same orientation as the orientation of magnetization (spin) of the reference layer 10. A spin angular momentum of the spin-polarized electrons is applied to the magnetization of the storage layer 11, and the magnetization orientation of the storage layer 11 is reversed to become identical to the magnetization orientation of the reference layer 10. When the magnetization orientation of the two magnetic layers 10 and 11 is parallel orientation, the resistance value of the MTJ element 1 decreases to a minimum. For example, “0” data is assigned to the MTJ element 1, whose magnetization orientation is parallel orientation.

When the magnetization orientation of the storage layer 11 and the magnetization orientation of the reference layer 10 are set in an antiparallel state, that is, when the magnetization orientation of the storage layer 11 is set to be opposite to the magnetization orientation of the reference layer 10, a current Iw, which flows from the reference layer 10 toward the storage layer 11, is supplied to the MTJ element 1. In this case, electrons move from the storage layer 11 toward the reference layer 10. Electrons with a spin, which is antiparallel to the magnetization orientation of the reference layer 10, are reflected by the reference layer 10. The reflected electrons are injected in the storage layer 11 as spin-polarized electrons. A spin angular momentum of the spin-polarized electrons (reflected electrons) is applied to the magnetization of the storage layer 11, and the magnetization orientation of the storage layer 11 is reversed to become opposite to the magnetization orientation of the reference layer 10. When the magnetization orientation of the two magnetic layers 10 and 11 is antiparallel orientation, the resistance value of the MTJ element 1 increases to a maximum. For example, “1” data is assigned to the MTJ element 1, whose magnetization orientation is antiparallel orientation.

In the STT-MRAM, the write circuit 181 includes a source circuit (e.g. a current source) for generating the write current Iw, and a sink circuit for receiving the write current Iw. At a time of data write of the STT-MRAM, one of two bit lines, which constitute a bit line pair, is connected to the source circuit, and the other of the two bit lines is connected to the sink circuit.

At a time of data read, a read current Ir, which is less than the magnetization reversal threshold of the storage layer 11, is supplied into the MTJ element 1. The data stored in the memory cell is read out by sensing a variation in magnitude of the read current Ir in accordance with the resistance state of the MTJ element.

In the MRAM of the first embodiment, the magnetization orientations of reference layers of magnetoresistive effect elements 1 in memory cells which neighbor each other in the X direction and Y direction (X-Y plane) are mutually different. Thereby, in the MRAM of this embodiment, a magnetic interference between magnetoresistive effect elements (memory cells), which is caused by a magnetic field occurring from the magnetoresistive effect elements, can be suppressed.

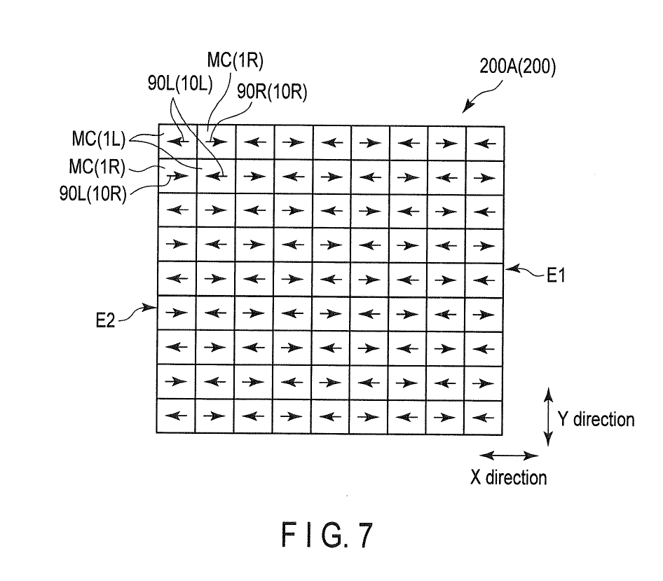

FIG. 7 is a plan view which schematically illustrates directions of magnetization of reference layers of magnetoresistive effect elements in the cell array of the MRAM of the embodiment.

In FIG. 7, one rectangle (box) corresponds to one memory cell MC (or MTJ element 1L, 1R). In FIG. 7, an arrow 90L, 90R in the rectangle is indicative of the direction of magnetization 90L, 90R of a reference layer 10L, 10R of an MTJ element 1L, 1R in each memory cell MC. FIG. 7 illustrates magnetization directions of reference layers of MTJ elements of an in-plane magnetization type.

In the embodiment, in a cell array 200A of a rectangular region, a side E1 on one end side (a right side in the drawing) in the X direction of the cell array 200A is referred to as “first side E1”, and a side E2 on the other end side (a left side in the drawing) in the X direction of the cell array 200A is referred to as “second side E2”.

As illustrated in FIG. 7, each of a plurality of memory cells provided in the cell array 200A includes an MTJ element 1R including a reference layer 10R with magnetization 90R (magnetization in a first direction) in a direction toward the first side E1, or an MTJ element 1L including a reference layer 10L with magnetization 90L (magnetization in a second direction) in a direction toward the second side E2.

In two memory cells MC neighboring in the X direction (e.g. row direction), the magnetizations of reference layers 10L, 10R (N poles of magnetic layers functioning as reference layers) of MTJ elements 1L, 1R in these two memory cells are directed in different directions (the direction toward the side E1 or side E2 of the cell array 200A).

The MTJ element 1R including the reference layer 10R with the magnetization 90R toward the first side E1 neighbors, in the X direction, the MTJ element 11 including the reference layer 10L with the magnetization 90L toward the second side E2.

The reference layer 10R with the magnetization 90R toward the first side E1 is magnetized in a direction from the second side E2 toward the first side E1. The reference layer 10L with the magnetization 90L toward the second side E2 is magnetized in a direction from the first side E1 toward the second side E2.

The MTJ elements 1R each including the reference layer 10R with the magnetization 90R toward the first side E1 and the MTJ elements 11 each including the reference layer 10L with the magnetization 90L toward the second side E2 are alternately arranged in the X direction in the cell array 200.

As illustrated in FIG. 7, in two memory cells MC neighboring in the Y direction (e.g. column direction), like the two memory cells MC neighboring in the X direction, the magnetizations 90L, 90R of reference layers 10L, 10R of MTJ elements 1L, 1R in these two memory cells are directed in different directions.

Each of memory cells arranged in the Y direction includes an MTJ element 1R including a reference layer 10R with magnetization 90R in a direction toward the first side E1, or an MTJ element 1L including a reference layer 10L with magnetization 90L in a direction toward the second side E2. The MTJ element 1R including the reference layer 10R with the magnetization 90R toward the first side E1 neighbors, in the Y direction, the MTJ element 1L including the reference layer 10L with the magnetization 90L toward the second side E2.

The MTJ elements 1R each including the reference layer 10R with the magnetization 90R toward the first side E1 and the MTJ elements 1L each including the reference layer 10L with the magnetization 90L toward the second side E2 are alternately arranged in the Y direction in the cell array 200A.

In memory cells MC neighboring in a direction crossing the X direction and Y direction (an oblique direction of the cell array 200) in a parallel direction to the surface of the semiconductor substrate, the magnetizations 90L, 90R of reference layers 10L, 10R of MTJ elements 1L, 1R, which neighbor in the oblique direction, are set in the same direction.

Specifically, in the cell array 200A, the MTJ elements 1R each including the reference layer 10R with the magnetization 90R toward the first side E1 are arranged in an oblique direction of the cell array 200, and the MTJ elements 11, each including the reference layer 10L with the magnetization 90L toward the second side E2 are arranged in an oblique direction of the cell array 200A.

In this manner, as regards the layout of reference layers 10L, 10R of MTJ elements 1L, 1R of plural memory cells MC in the cell array 200A, the reference layers 10L, 10R with opposite directions of magnetizations 90L, 90R are alternately arranged in the X direction and Y direction of the cell array 200A. This arrangement pattern of reference layers (MTJ elements) in the cell array 200A is referred to as “checker pattern”.

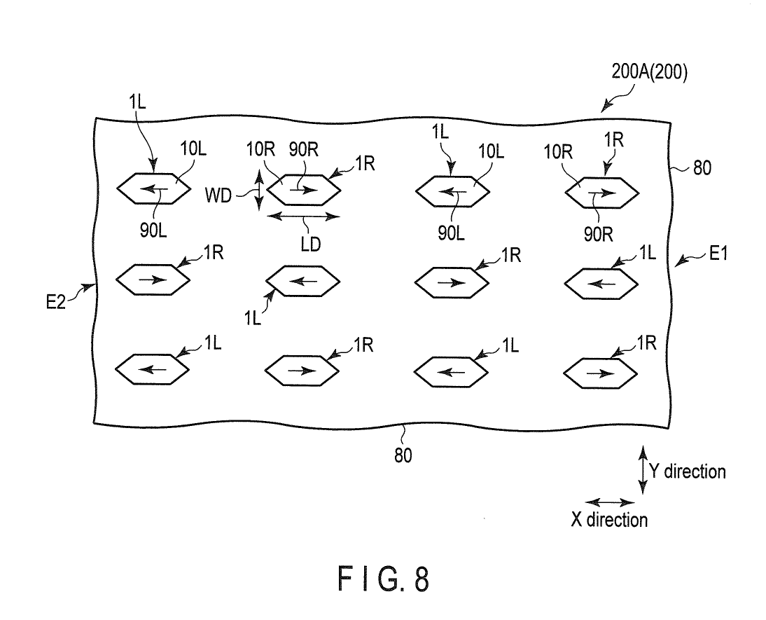

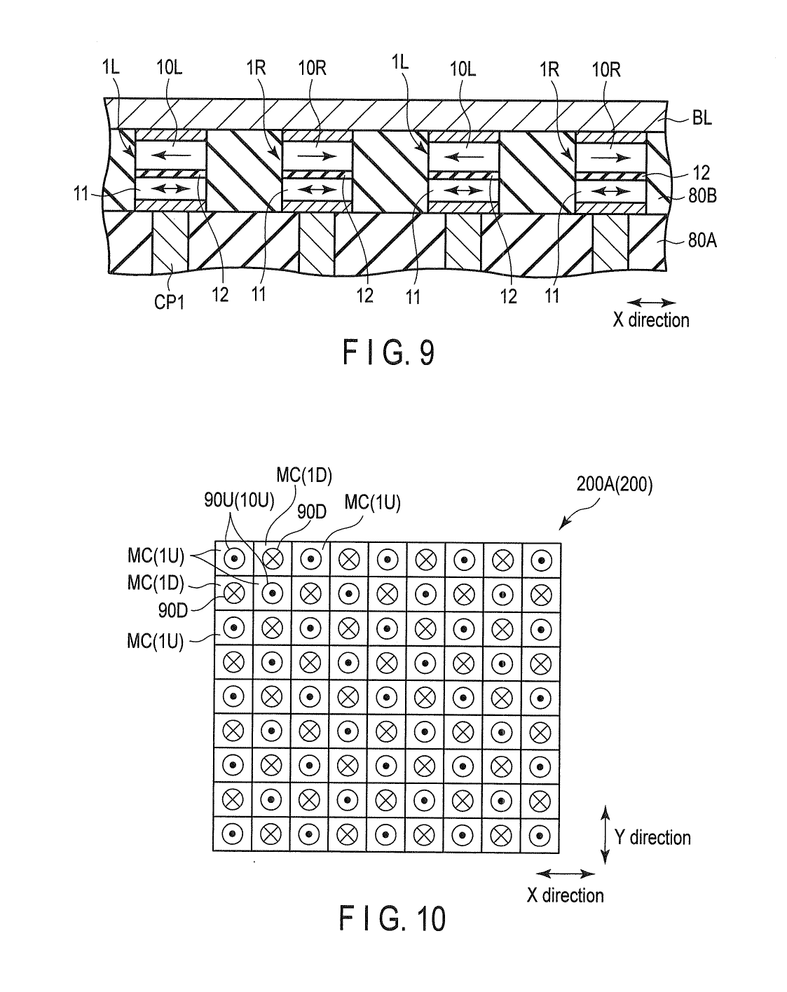

Referring to FIG. 8 and FIG. 9, a description is given of the structures of MTJ elements in the cell array in the MRAM of the present embodiment.

FIG. 8 is a top view which schematically illustrates plan-view shapes of MTJ elements in the cell array. FIG. 9 is a cross-sectional view which schematically illustrates cross-sectional shapes of MTJ elements in the cell array. In FIG. 8 and FIG. 9, depiction of structural elements (e.g. cell transistors) in the memory cells, other than the MTJ elements, is omitted.

As illustrated in FIG. 8 and FIG. 9, MTJ elements 1L, 1R are provided on an interlayer insulation film 80A. Bottom portions of the MTJ elements 1L, 1R are connected to contact plugs CP1. The MTJ elements 1L, 1R are covered with an interlayer insulation film 80B.

Plural MTJ elements 1L, 1R, which are arranged in the X direction, are commonly connected to a bit line BL which is provided on the interlayer insulation film 80B.

The magnetic anisotropy (in-plane magnetic anisotropy) of the reference layer 10L, 10R (and storage layer), which is included in the MTJ element 1L, 1R of the in-plane magnetization type, depends on the shape of the magnetic layer. The magnetization orientation of the magnetic layer 10L, 10R based on the shape magnetic anisotropy is parallel to a longitudinal direction LD of the magnetic layer 10L, 10R. In the example illustrated in FIG. 8, in the in-plane magnetization-type MTJ element 1L, 1R, the shape of the magnetic layer 10L, 10R is set such that the longitudinal direction (major-axis direction) of the magnetic layer (reference layer) 10L, 10R is substantially parallel to the X direction. A width direction (transverse direction, minor-axis direction) WD of the magnetic layer 10L, 10R is substantially parallel to the Y direction.

For example, the reference layer (and storage layer) 10L, 10R of the MTJ element 1L, 1R has a hexagonal plan-view shape. However, the plan-view shape of the reference layer (and storage layer) 10L, 10R of the MTJ element 1L, 1R may be elliptic.

In the example illustrated in FIG. 8 and FIG. 9, the case is illustrated that the magnetization orientation of the magnetic layer 10L, 10R of the MTJ element 1L, 1R is parallel to the X direction. Alternatively, the magnetization orientation of the magnetic layer 10L, 10R of the MTJ element 1L, 1R may be parallel to the Y direction.

FIG. 10 to FIG. 12 illustrate an example in which the MRAM of the embodiment is formed of memory cells including vertical magnetization-type MTJ elements.

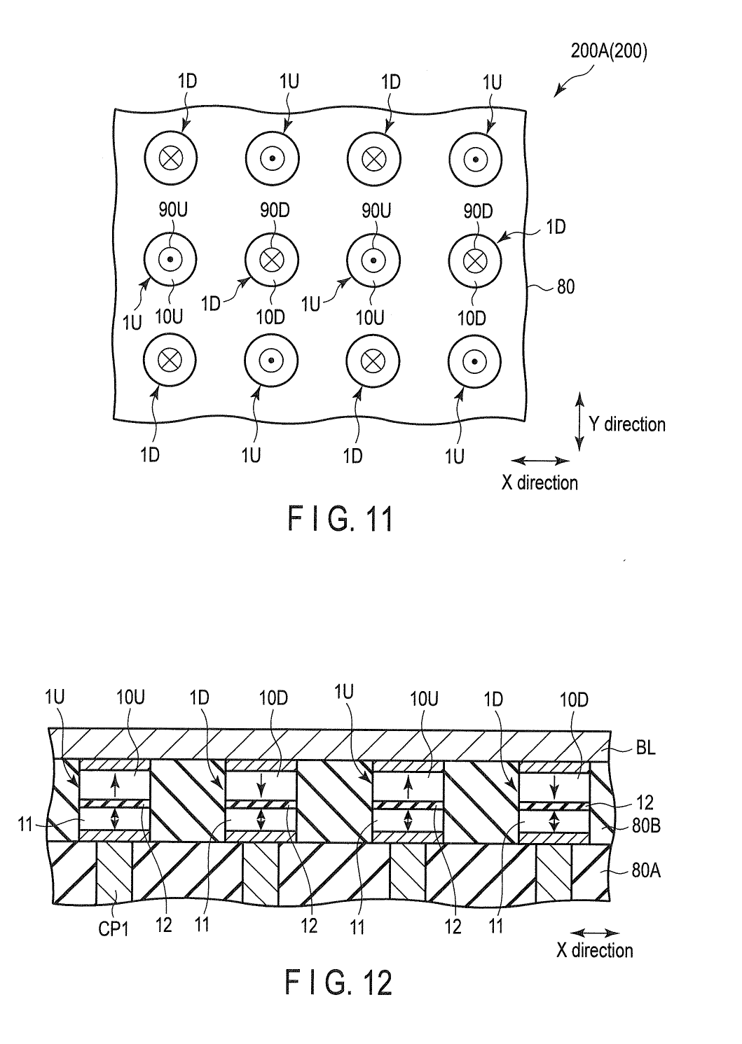

FIG. 10 is a top view which schematically illustrates magnetization directions of reference layers of magnetoresistive effect elements in the cell array of the MRAM of the embodiment. FIG. 11 is a top view which schematically illustrates plan-view shapes of MTJ elements in the cell array. FIG. 12 is a cross-sectional view which schematically illustrates cross-sectional shapes of MTJ elements in the cell array. In FIG. 11 and FIG. 12, depiction of structural elements (e.g. cell transistors) in the memory cells, other than the MTJ elements, is omitted.

As illustrated in FIG. 10, in memory cells MC including vertical magnetization-type MTJ elements 1U, 1D, reference layers 10U, 10D may be arranged in the cell array 200 such that magnetizations 90U, 90D of the reference layers 10U, 10D have a layout of a checker pattern.

As illustrated in FIG. 11 and FIG. 12, the vertical magnetization-type MTJ element 1U, 1D has, for example, a circular or elliptic plan-view shape.

The MTJ elements 1D each including the reference layer 10D with the magnetization (downward magnetization) 90D toward the semiconductor substrate and the MTJ elements 1U each including the reference layer 10U with the magnetization (upward magnetization) 90U toward the opposite side (bit line side) to the semiconductor substrate are alternately arranged in the X direction and Y direction.

The magnetization directions of the reference layers 10D, 10U of the MTJ elements 1D, 1U, which neighbor each other in the X direction and Y direction, are mutually different. The magnetization directions of the reference layers 10D, 10U of the MTJ elements 1D, 1U, which are arranged in a direction oblique to the X direction and Y direction in a parallel direction to the surface of the semiconductor substrate, are identical.

The manufacturing method of the MRAM of the embodiment is as follows.

Cell transistors of memory cells are formed on a semiconductor substrate. An interlayer insulation film is deposited on the semiconductor substrate on which the cell transistors have been formed. Contact plugs, which are connected to sources/drains of the cell transistors, are formed in the interlayer insulation film at predetermined positions of the semiconductor substrate.

Structural parts of MTJ elements are deposited on the interlayer insulation film on the semiconductor substrate.

For example, the structural parts of the MTJ elements are deposited such that a lower electrode layer, a first magnetic layer, a nonmagnetic layer (tunnel barrier layer), a second magnetic layer and a mask layer (upper electrode layer) are successively stacked on the interlayer insulation film.

The mask layer is patterned by lithography and etching so as to correspond to the pattern of each of MTJ elements which are to be formed in the cell array, and a plurality of hard masks are formed on the magnetic layer. Using the hard masks as a mask, the second magnetic layer, nonmagnetic layer, first magnetic layer and lower electrode layer, which are located under the hard masks, are successively processed. Thereby, MTJ elements are formed on the interlayer insulation film.

The magnetization directions of reference layers of the MTJ elements are controlled by a combination of the application of at least one magnetic field to the semiconductor substrate on which the MTJ elements (or magnetic layers) are formed, the supply of an electric current to the MTJ elements 1 (e.g. control of magnetization directions by STT) and the selective fabrication of magnetic layers.

Thereby, the MTJ elements 1R each including the reference layer 10R with the magnetization 90R toward the first side E1 and the MTJ elements 1L each including the reference layer 10L with the magnetization 90L toward the second side E2 are formed in the cell array 200A such that these MTJ elements are alternately arranged in the X direction and Y direction.

Thus, an MRAM, in which the magnetizations of the reference layers 10L, 10R have a checker pattern in the cell array 200, is formed.

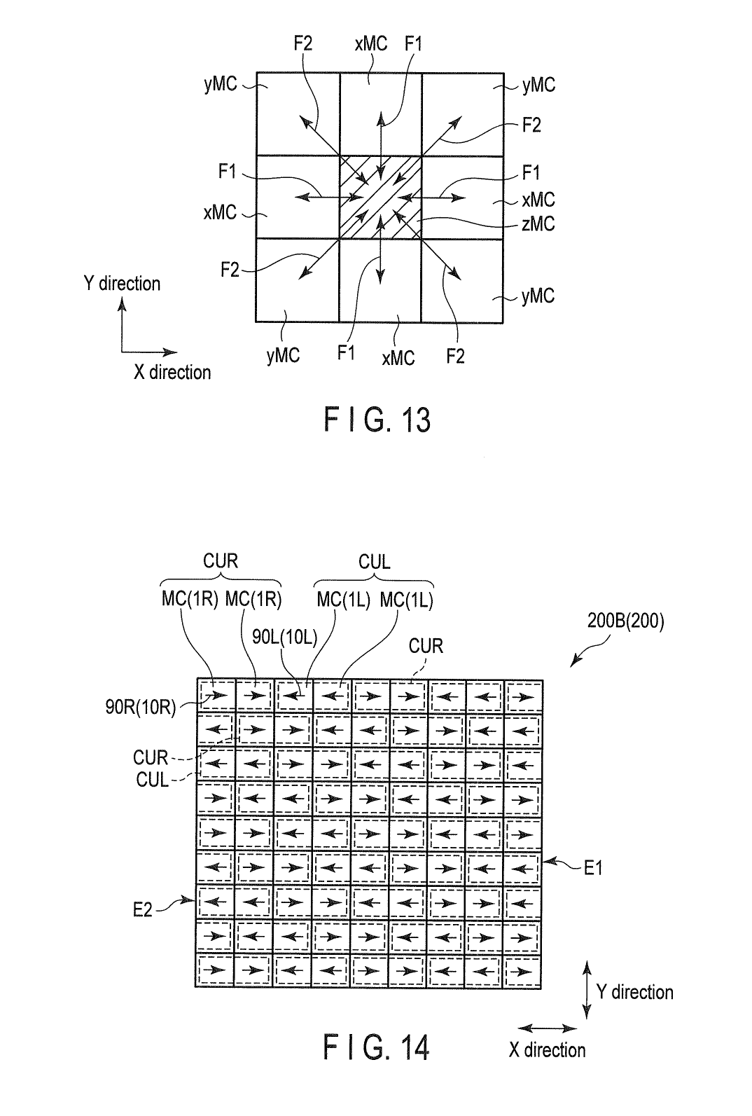

FIG. 13 is a view for explaining a magnetic interference between memory cells of the MRAM of the embodiment.

For the purpose of simple description, attention is paid to a certain one memory cell (MTJ element) in a region of 3×3 memory cells in the cell array, and a description is given of a magnetic interference occurring between this memory cell and the other cells (hereinafter referred to as “neighboring cells”) which neighbor this memory cell.

Eight memory cells (neighboring cells) xMC, yMC directly neighbor a certain memory cell zMC. The eight neighboring cells xMC, yMC surround the memory cell zMC.

Four neighboring cells xMC of the eight neighboring cells neighbor the memory cell zMC in the X direction or Y direction. The other four neighboring cells yMC of the eight neighboring cells neighbor the memory cell zMC in oblique directions.

For the purpose of simple description, it is assumed that the plan-view shape of the memory cell is square, and the distance between the centers of the memory cells is set to be the distance between the memory cells. In this case, the distance between two memory cells neighboring in the x direction and the distance between two memory cells neighboring in the Y direction are expressed by “L1”. The distance between two memory cells neighboring in the oblique direction is expressed by “L2”. When the plan-view shape of the memory cell is square, the relationship between the distance L1 and distance L2 is L2=(√2)×L1.

In the MTJ element, the magnetic pole of the storage layer is expressed by “mp1”, and the magnetic pole of the reference layer is expressed by “mp2”. For the purpose of simple description, it is assumed that the magnitude of the magnetic pole mp1 is equal to the magnitude of the magnetic pole mp2, and the magnetic pole is expressed by “mp”.

A magnetic force F1, which occurs between a certain memory cell zMC and one memory cell xMC neighboring in the X direction or Y direction, is expressed by mp²/(4πμ×L1²), based on the Coulomb's law of magnetic force.

In addition, a magnetic force F2, which occurs between a certain memory cell zMC and one memory cell yMC neighboring in the oblique direction, is expressed by mp²/(4πμ×L2²)=mp²/(4πμ×2×L1²).

When the magnetization directions of the reference layers of the MTJ elements of the memory cells in the cell array are all identical, the sum of magnetic forces applied from the neighboring cells xMC, yMC to the memory cell zMC is expressed by 4×F1+4×F2=6×F1.

When the magnetization directions of the reference layers of the MTJ elements of the memory cells, which neighbor in the X direction and Y direction, are opposite to each other, as in the present embodiment, the sum of magnetic forces applied to the memory cell zMC from the neighboring cells xMC, yMC is expressed by 4×F1−4×F2=2×F1, since the magnetization direction of the neighboring cells in the X/Y direction and the magnetization direction of the neighboring cells in the oblique directions are opposite to each other.

In this manner, by making the magnetization directions of the reference layers of the MTJ elements different between the neighboring memory cells in the cell array, the influence of magnetic fields between the surrounding MTJ elements and the central MTJ element can be reduced.

In order to improve the storage density of the memory, the memory cells and MTJ elements in the MRAM are reduced in size.

If the distance between the storage layer and reference layer in the MTJ element and the distance between the MTJ elements are decreased as a result of microfabrication of the memory cells and MTJ elements, it is possible that the magnetic interference between the MTJ elements due to magnetic fields (magnetism), which occur from the MTJ elements, increases.

At a time of data write, it is possible that a variation in magnetization reversal threshold of the storage layer due to a magnetic interference between MTJ elements is caused by a magnetic field between a neighboring cell and a selected cell, and no magnetization reversal occurs or a data write defect occurs due to thermal agitation.

At a time of data read, it is possible that a shift in magnetic resistance of the MTJ element due to a magnetic interference between MTJ elements is caused by a magnetic field between a neighboring cell and a selected cell, and a defect occurs in data determination using a certain determination level (read level).

In addition, at a time of data hold (retention), it is possible that the magnetization direction of the storage layer of the MTJ element in a certain memory cell is unintentionally reversed by a magnetic interference between MTJ elements.

In the MRAM of the present embodiment, as regards mutually neighboring memory cells, the directions of magnetization 90L, 90R of reference layers 10L, 10R of MTJ elements 1L, 1R are mutually different.

For example, in the MRAM of the embodiment, the MTJ elements 1R each including the reference layer 10R with the magnetization 90R toward the first side E1 and the MTJ elements 1L each including the reference layer 10L with the magnetization 90L toward the second side E2, which is opposed to the first side E1 in the parallel direction to the surface of the semiconductor substrate, are alternately arranged in the X direction and Y direction.

In this manner, as regards the memory cells neighboring in the X direction and Y direction (X-Y plane), the layout pattern of magnetization of the reference layers 10L, 10R in the cell array 200A is designed such that the directions of the magnetization 90L, 90R of the reference layers 10L, 10R of the MTJ elements 1L, 1R are opposite to each other. Thereby, the magnitude of magnetism (magnetic field), which is applied to the MTJ element of a certain memory cell from the surrounding memory cells, can be reduced.

As a result, as regards the MTJ elements 1R, 1L of the memory cells in the cell array 200A, the layout pattern of magnetization directions of the reference layers shown in FIG. 7 and FIG. 10 can reduce the magnetic interference between the memory cells and between the MTJ elements.

Therefore, the magnetic memory of the first embodiment can improve the reliability of the magnetic memory.

### (2) Second Embodiment

Referring to FIG. 14 to FIG. 15, a magnetic memory (e.g. MRAM) according to a second embodiment will be described. In the magnetic memory of the second embodiment, the same structural elements as in the first embodiment are denoted by like reference numerals, and a description thereof will be given where necessary.

FIG. 14 is a plan view which schematically illustrates magnetization directions of reference layers of magnetoresistive effect elements in the cell array in the MRAM of the second embodiment.

In FIG. 14, like the first embodiment, one rectangle (box) corresponds to one memory cell (or MTJ element), and an arrow 90L, 90R in the rectangle is indicative of the direction of magnetization of a reference layer of an in-plane magnetization-type MTJ element in each memory cell.

As illustrated in FIG. 14, two memory cells (MTJ elements), which neighbor in the X direction, constitute one pair CUL, CUR. The reference layers 10L, 10R of the MTJ elements in the two memory cells MC, which constitute the pair CUL, CUR, have the same direction of magnetization.

The two memory cells MC, which form one pair CUL, CUR, are referred to as “cell unit CUL, CUR”. Incidentally, at a time of an operation of the MRAM, the two memory cells in the cell unit are independently driven.

In the description below, a layout pattern, in which cell units each composed of a pair of memory cells are arranged in the cell array, is referred to as “pair pattern”.

In a cell array 200B having the layout of the pair pattern, the magnetizations 90L, 90R of reference layers 10L, 10R of MTJ elements 1L, 1R of memory cells in two cell units CUL, CUR, which neighbor in the X direction, are opposite to each other.

The MTJ elements 1R in one cell unit CUR of the two cell units CUL, CUR, which neighbor in the X direction, include reference layers 10R with magnetization 90R toward the first side E1, and the MTJ elements 1L in the other cell unit CUL include reference layers 10L with magnetization 90L toward the second side E2.

In the Y direction, two memory cells MC in a certain cell unit CUL, CUR neighbor memory cells MC of mutually different cell units CUL, CUR.

In the MTJ elements 1L, 1R in cell units CUL, CUR which neighbor in the Y direction, the directions of the magnetization 90R of the reference layers 10R of two MTJ elements 1R which neighbor in the Y direction are identical to each other, and the directions of the magnetization 90R, 90L of the reference layers 10R, 10L of the other two MTJ elements which neighbor in the Y direction are different from each other. For example, in four memory cells MC in a 2×2 region of the cell array 200B, the magnetization directions of the reference layers of three MTJ elements of the four MTJ elements 1L, 1R are identical, and the magnetization direction of the reference layer of the other MTJ element is opposite to the magnetization directions of the reference layers of the three MTJ elements.

A cell unit CUL, CUR neighbors two cell units CUL, CUR, which neighbor in the X direction, in oblique directions to the X direction and Y direction (X-Y plane) in a parallel direction to the surface of the substrate. The cell unit, which is located in the oblique directions to the two cell units CUL, CUR that neighbor in the X direction, neighbors one cell unit CUL of the two cell units CUL, CUR that neighbor in the X direction, in a third direction parallel to a diagonal line of the cell array 200B (for example, a line connecting a corner C1, which is defined by the side E2 and a side E3, and a corner C3 which is defined by the side E1 and a side E4), and neighbors the other cell unit CUR in a fourth direction parallel to a diagonal line of the cell array 200B (for example, a line connecting a corner C2 which is defined by the side E1 and side E3, and a corner C4 which is defined by the side E2 and side E4) which crosses the third direction.

For example, in the memory cells (MTJ elements) in the two cell units neighboring in the third direction, the magnetization directions of the reference layers 10L, 10R are identical. In the third direction (the direction parallel to the diagonal line (C1-C3 direction) of the cell array), a plurality of cell units, which include MTJ elements 1L, 1R including reference layers 10L, 10R with the same direction of magnetization 90L, 90R, are arranged.

In the memory cells (MTJ elements) in the two cell units neighboring in the fourth direction, the magnetization directions of the reference layers are opposite to each other. In the fourth direction (the direction parallel to the C2-C4 direction) crossing the third direction, cell units CUR, which include MTJ elements 1R including reference layers 10R with the magnetization direction toward the first side E1, and cell units CUL, which include MTJ elements 1L including reference layers 10L with the magnetization direction toward the second side E2, are alternately arranged.

As illustrated in FIG. 14, In the cell array 200B having the layout of the pair pattern, as regards memory cells neighboring on one end side and the other end side of a certain memory cell in the X direction, the direction of magnetization 90R of the reference layer 10R of the MTJ element of the memory cell neighboring on the one end side is opposite to the direction of magnetization 90L of the reference layer 10L of the MTJ element of the memory cell neighboring on the other end side. As regards memory cells neighboring on one end side and the other end side of a certain memory cell in the Y direction, the direction of magnetization 90R of the reference layer 10R of the MTJ element 1R of the memory cell neighboring on the one end side is opposite to the direction of magnetization 90L of the reference layer 10L of the MTJ element 1L of the memory cell neighboring on the other end side.

Since the magnetization directions of the reference layers of the memory cells, which are opposed to each other in the X direction or Y direction with a certain memory cell interposed, are opposite to each other, the magnetic fields which are applied to the certain memory cell from the memory cells neighboring in the X direction or Y direction, are canceled.

In the cell array 200B of the pair pattern, as regards two memory cells which are opposed to each other in an oblique direction with a certain memory cell interposed, the directions of magnetizations 90L, 90R of the reference layers 10L, 10R of the MTJ elements are identical.

As regards four memory cells neighboring a certain memory cell in oblique directions, the direction of magnetization 90L (90R) of each reference layer 10L (10R) in the two memory cells on one straight line is identical to the direction of magnetization 90L (90R) of the reference layer 10L (10R) of the certain memory cell, and the direction of magnetization 90R (90L) of each reference layer 10R (10L) in the two memory cells on the other straight line is opposite to the direction of magnetization 90L (90R) of the reference layer 10L (10R) of the certain memory cell.

Thereby, the magnetic force between the four neighboring cells, which neighbor in the oblique directions, and the certain memory cell is canceled.

In the example described with reference to FIG. 13, in the memory cells in the 3×3 region of the cell array 200B of the pair pattern, the magnitude of the magnetic field, which is applied to the memory cell zMC at the center of this region, is 2×F1−2×F1+2×F2−2×F2=0.

In this manner, with the layout pattern of magnetization of reference layers of MTJ elements by the pair pattern, the magnetic interference between memory cells becomes substantially zero.

In the meantime, FIG. 15 is a schematic view illustrating a layout of magnetization directions of reference layers, with use of a pair pattern of vertical magnetization-type MTJ elements.

As illustrated in FIG. 15, in the MRAM in which vertical magnetization-type MTJ elements are used, two mutually neighboring MTJ elements (memory cells) constitute one cell unit CUD, CUU, and the magnetization directions of reference layers of the MTJ elements, which constitute the cell unit CUD, CUU, are identical. The magnetization directions of reference layers of two units CUD, CUU, which neighbor in the X direction, are different from each other.

In the pair pattern CUD, CUU using the vertical magnetization-type MTJ elements shown in FIG. 15, like the pair pattern using in-plane magnetization-type MTJ elements, the magnetic interference between memory cells can be reduced to substantially zero.

Incidentally, since the manufacturing method of the magnetic memory of this embodiment is substantially the same as in the first embodiment, a description thereof is omitted here.

As has been described above, according to the present embodiment, by forming the cell array having the layout pattern of magnetization 90L, 90R of reference layers 10L, 10R of MTJ elements 1L, 1R as shown in FIG. 14 and FIG. 15, the influence of the magnetic interference between memory cells due to the magnetization of magnetoresistive effect elements can be reduced.

Therefore, according to the magnetic memory of the second embodiment, the reliability of the magnetic memory can be improved.

### (3) Third Embodiment

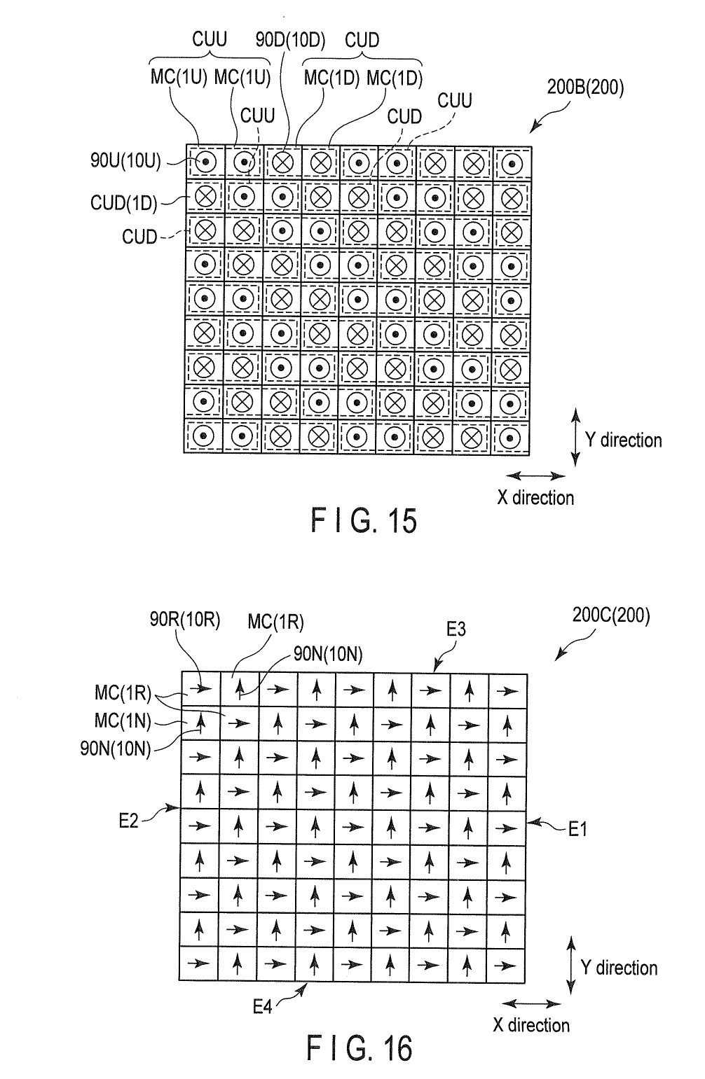

Referring to FIG. 16 to FIG. 19, a magnetic memory (e.g. MRAM) according to a third embodiment will be described. In the third embodiment, the structural elements, which are substantially the same as those in the first and second embodiments, are denoted by like reference numerals, and a description thereof is omitted.

In the MRAM of the third embodiment, MTJ elements are laid out in the cell array such that the direction (magnetization orientation) of magnetic anisotropy of a reference layer of a magnetoresistive effect element of one of two memory cells, which neighbor in the X direction and Y direction, crosses the direction (magnetization orientation) of magnetic anisotropy of a reference layer of a magnetoresistive effect element of the other memory cell. The MTJ elements used in the MRAM of this embodiment are in-plane magnetization-type MTJ elements.

FIG. 16 is a schematic view illustrating magnetization directions of reference layers of MTJ elements in the cell array of the MRAM of the third embodiment. In FIG. 16, like the first and second embodiments, one rectangle (box) corresponds to one memory cell (or MTJ element), and an arrow in the rectangle is indicative of the direction of magnetization of a reference layer of an in-plane magnetization-type MTJ element in each memory cell.

In the embodiment, for the purpose of simple description, in a cell array with a rectangular planar structure, a side on one end side in the X direction is referred to as “first side E1”, a side on the other end side in the X direction is referred to as “second side E2”, a side on one end side in the Y direction is referred to as “third side E3”, and a side on the other end side in the Y direction is referred to as “fourth side E4”. The first end E1 and the third end E3 is at right angle to each other. The second end E2 and the fourth end E4 is at right angle to each other.

As illustrated in FIG. 16, in a plurality of memory cells MC in a cell array 200C, MTJ elements 1R each including a reference layer 10R with a magnetic anisotropy (in-plane magnetic anisotropy) in a direction parallel to the X direction and MTJ elements 1N each including a reference layer 10N with a magnetic anisotropy (in-plane magnetic anisotropy) in a direction parallel to the Y direction are provided in the cell array 200C.

The reference layer 10R with the magnetic anisotropy parallel to the X direction is magnetized in a direction from the second side E2 toward the first side E1, and the magnetization 90R of the reference layer 10R is directed toward the first side E1 of the cell array 200C. The reference layer 10N with the magnetic anisotropy parallel to the Y direction is magnetized in a direction from the fourth side E4 toward the third side E3, and the magnetization 90N of the reference layer 10N is directed toward the third side E3 of the cell array 2000.

Along the X direction of the cell array 200C, reference layers 10R with the magnetization 90R toward the first side E1 and reference layers 10N with the magnetization 90N toward the third side E3 are alternately arranged. Along the Y direction of the cell array 200C, reference layers 10R with the magnetization 90R toward the first side E1 and reference layers 10N with the magnetization 90N toward the third side E3 are alternately arranged.

In the meantime, the magnetization 90N, 90R of the reference layers 10N, 10R, which are arranged in an oblique direction to the X direction and Y direction, with respect to a parallel direction to the surface of the cell array 200C, is directed toward the same side (in this example, the first side E1 or third side E3) of the cell array 2000.

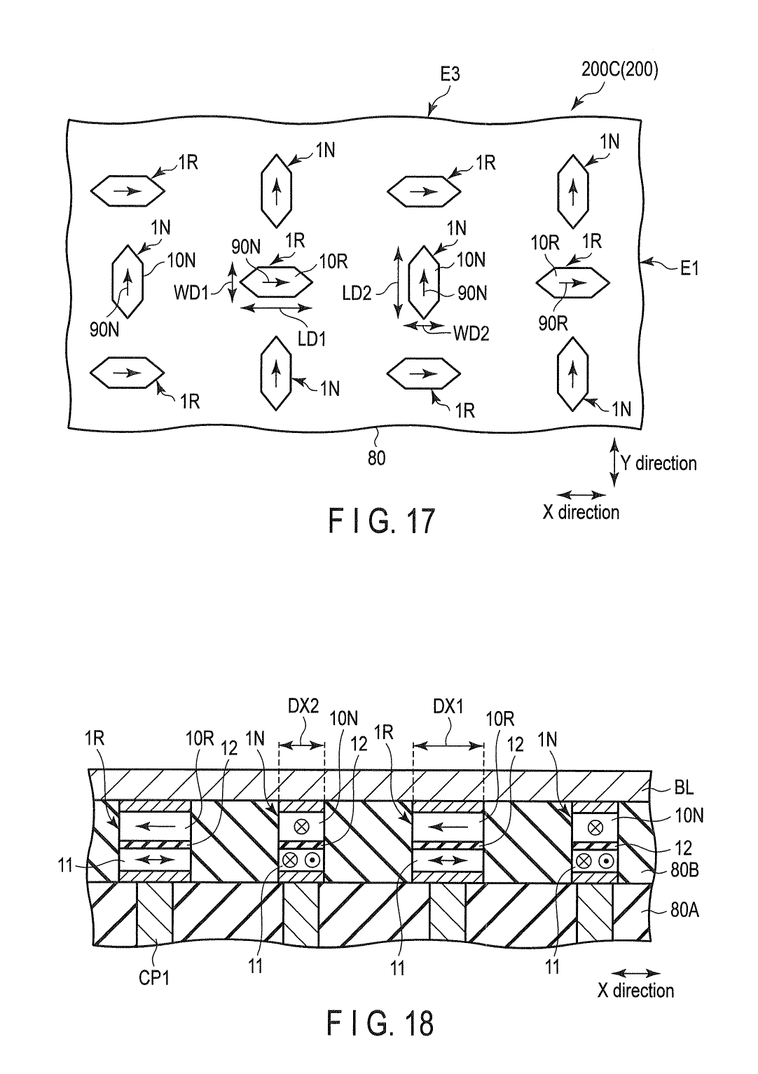

FIG. 17 is a top view which schematically illustrates structures of MTJ elements in memory cells in the cell array of the MRAM of the embodiment. FIG. 18 is a cross-sectional view which schematically illustrates structures of MTJ elements in memory cells in the cell array of the MRAM of the embodiment.

As illustrated in FIG. 17 and FIG. 18, in the embodiment, the in-plane magnetization-type MTJ element 1R, 1N has a hexagonal plan-view shape.

The reference layer 10R with the magnetic anisotropy parallel to the X direction of the cell array 200C has a plan-view shape which a longitudinal direction LD1 of the reference layer 10R is parallel to the X direction. The reference layer 10R with the magnetic anisotropy parallel to the X direction has a plan-view shape with a width direction WD1 of the layer 10R parallel to the Y direction. Incidentally, a storage layer 11, which corresponds to the reference layer 10R with the magnetic anisotropy parallel to the X direction, has the same plan-view shape as this reference layer and is magnetized in the same orientation as that of the reference layer 10R.

The reference layer 10N with the magnetic anisotropy parallel to the Y direction of the cell array 200C has a plan-view shape with a longitudinal direction LD2 of the layer 10N parallel to the Y direction. The reference layer 10N with the magnetic anisotropy parallel to the Y direction has a plan-view shape with a width direction WD2 parallel to the X direction. Incidentally, a storage layer 11, which corresponds to the reference layer 10N with the magnetic anisotropy parallel to the Y direction, has the same plan-view shape as this reference layer 10N and is magnetized in the same orientation as that of the reference layer 10N.

In a cross section of the cell array 200C along the X direction, a dimension DX1 in the X direction of the MTJ element 1R with the magnetic anisotropy (in-plane magnetic anisotropy) parallel to the X direction is greater than a dimension DX2 in the X direction of the MTJ element 1N with the magnetic anisotropy (in-plane magnetic anisotropy) parallel to the Y direction.

In the meantime, in the present embodiment, the plan-view shape of the MTJ element 1R, 1N may be an elliptic shape with a major axis in the X direction or Y direction. The element size (area) of the MTJ element 1R with the magnetic anisotropy in the X direction is substantially equal to the element size of the MTJ element 1N with the magnetic anisotropy in the Y direction.

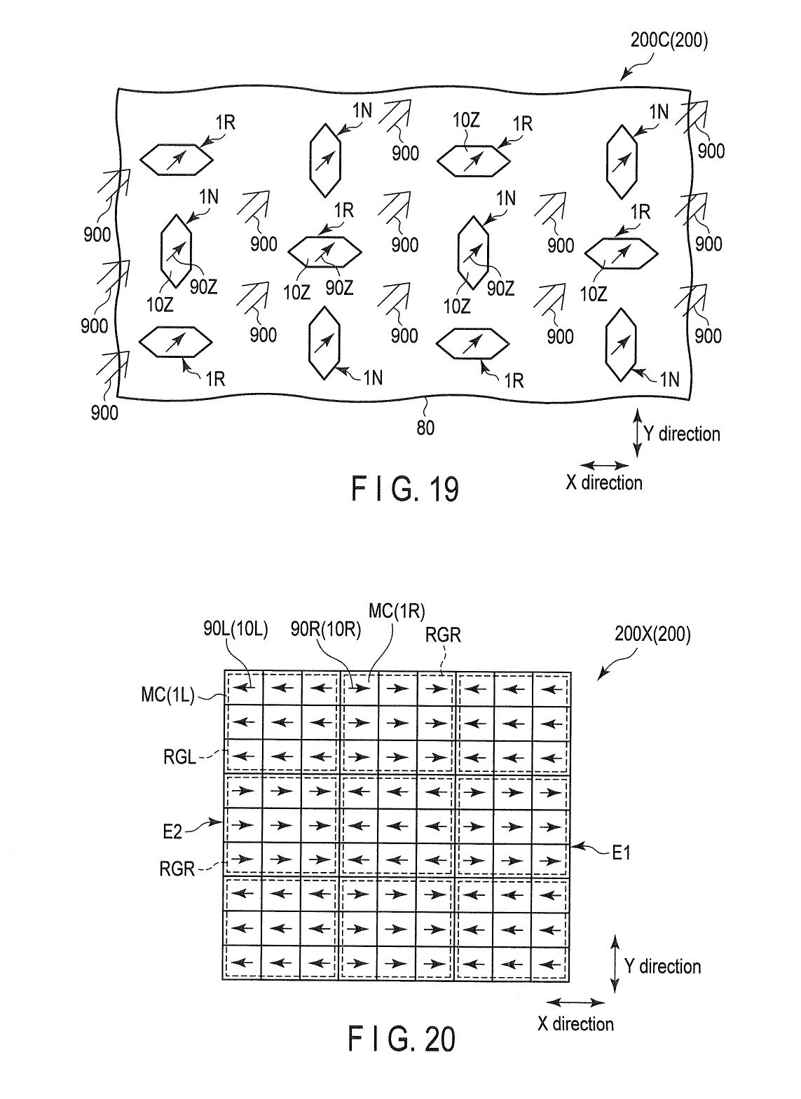

Referring to FIG. 19, a manufacturing method of the MRAM (magnetic memory) of the present embodiment is described. FIG. 19 is a schematic view for describing the manufacturing method of the MRAM of the embodiment.

Like the manufacturing method of the MRAM described in the first embodiment, after cell transistors are formed on a semiconductor substrate, structural parts (a multilayer structure including magnetic layers, a tunnel barrier layer and electrodes) of MTJ elements are successively deposited on an interlayer insulation film 80 which covers the semiconductor substrate.

Hard masks showing patterns of MTJ elements to be formed are formed on the multilayer structure. Each hard mask has a hexagonal plan-view shape. Hard masks with mask patterns, whose longitudinal direction is parallel to the X direction, and hard masks with mask patterns, whose longitudinal direction is parallel to the Y direction, are laid out on the interlayer insulation film 80 so as to be alternately arranged in the X direction and alternately arranged in the Y direction. Incidentally, hard masks, which are arranged on the same straight line in an oblique direction to the X direction and Y direction in the X-Y plane, are laid out on the interlayer insulation film 80 such that the longitudinal directions of these hard masks are aligned in the same direction.

The plural hard masks, which are arranged in the oblique direction to the X direction and Y direction, have longitudinal directions of patterns, which are set in the same direction.

Based on the patterns of the hard masks, the multiplayer structure including the structural parts of the MTJ elements is processed by, for example, ion milling.

As illustrated in FIG. 19, after the MTJ elements 1R with patters (plan-view shapes of the elements), whose longitudinal direction is parallel to the X direction, and the MTJ elements 1N with patters, whose longitudinal direction is parallel to the Y direction, are formed, the MTJ elements 1R, 1N are subjected to an anneal process in the state in which a magnetic field 900 is applied to the semiconductor substrate. The magnetic 900 that is applied is set at about a magnitude of a saturation magnetic field of a magnetic layer 10Z which becomes the reference layer. In addition, the direction of the magnetic field 900 that is applied is set to be an oblique direction to the X direction and Y direction in a parallel direction to the surface of the semiconductor substrate, the oblique direction being, in this example, a direction from the corner C4 formed between the side E2 and side E4 of the cell array 200 toward the corner C2 formed between the side E1 and side E3. Thereby, the reference layers 10Z of the MTJ elements 1N, 1R are magnetized.

After the reference layers 10Z of the MTJ elements 1N, 1R are magnetized, the application of the magnetic field 900 is terminated.

After the magnetic field 900 is eliminated, the heating process is terminated and cooling is performed.

By the shape magnetic anisotropy of the magnetic layer 10Z, magnetization 90Z of the reference layer 10Z becomes parallel to the longitudinal direction of the plan-view shape of each MTJ element 1R, 1N.

In this manner, by the application of the magnetic field 900 in the oblique direction to the X direction and Y direction during the anneal process, as regards the reference layer 10R with the magnetization 90R parallel to the X direction, the magnetization 90R of the reference layer 10R is directed to the first side E1 of the cell array 200C, as illustrated in FIG. 17. As regards the reference layer 10N with the magnetization 90N parallel to the Y direction, the magnetization 90N of the reference layer 10N is directed to the third side E3 of the cell array 2000.

By the above manufacturing process, the MRAM having the layout of the directions of magnetization 90N, 90R of reference layers 10N, 10R in the cell array 200C, as illustrated in FIG. 16, is formed.

In the meantime, if the directions of magnetic anisotropy of the reference layers of the MTJ elements of the memory cells MC, which neighbor in the X direction and Y direction, cross each other, the magnetization of the reference layer 10 may be directed toward the second side E2, or may be directed toward the fourth side E4.

In the present embodiment, the magnitude of the magnetic force, which is applied between memory cells (MTJ elements) in the memory cells in the 3×3 region, is about 4×F1×cos(π/2)+4×F2=2×F1.

As described above, the directions of magnetic anisotropy (magnetization orientation) of the reference layers 10N, 10R of the MTJ elements 1N, 1R of the memory cells, which neighbor in the X direction and Y direction, are set to cross each other, as in the arrangement pattern of magnetizations of the reference layers 10N, 10R of MTJ elements 1N, 1R in the cell array 200C shown in FIG. 16 to FIG. 18. Thereby, compared to the arrangement pattern in which the magnetization directions of reference layers are all identical, the magnetic field, which is applied to a certain memory cell from neighboring cells, can be reduced.

Therefore, in the present embodiment, like the first and second embodiments, the magnetic interference between memory cells can be reduced.

Thus, according to the third embodiment, the reliability of the memory can be improved.

### (4) Modification

Referring to FIG. 20 to FIG. 22, a description is given of modifications of the magnetic memories (e.g. MRAMs) of the embodiments. Incidentally, the structural elements, which are substantially the same as in the MRAMs of the first to third embodiments, are denoted by like reference numerals, and a description thereof is omitted.

In the first to third embodiments, the cell arrays are illustrated, which are configured such that the magnetization directions of the reference layers of the magnetoresistive effect elements in the memory cells, which neighbor in the X direction and Y direction, are different from each other.

However, a plurality of regions may be set in the cell array, and the magnetization directions of reference layers of plural magnetoresistive effect elements may be different from each other in the regions neighboring in the X direction and Y direction. In the plural magnetoresistive effect elements in one region, the magnetization directions of plural reference layers are all identical.

FIG. 20 is a schematic view for describing the layout of reference layers of MTJ elements in the cell array of an MRAM according to a modification of the first embodiment.

As illustrated in FIG. 20, a plurality of regions RGL, RGR are provided in a cell array 200X. Each region RGL, RGR is a 3×3 region including nine memory cells MC. The MTJ element 1L, 1R in the memory cell MC is an in-plane magnetization-type MTJ element.

In the cell array of the MRAM of FIG. 20, a cell array 200X with a checker pattern layout is formed in units of the region RGL, RGR which is set in the cell array.

The magnetizations 90L, 90R of reference layers 10L, 10R of MTJ elements 1L, 1R in each region RGL, RGR are directed in the same direction (toward the same side of the cell array).

In the MTJ elements 1R of a certain region RGR, the reference layers 10R have the magnetization 90R in a first direction toward the first side E1 of the cell array 200X.

In the MTJ elements 1L of respective regions RGL which neighbor this region RGR, the reference layers 10L have the magnetization 90L in a second direction toward the second side E2 of the cell array 200X. The region RGR, in which the MTJ elements 1R including the reference layers 10R with the magnetization 90R in the first direction are arranged, neighbors in the Y direction the region RGL in which the MTJ elements including the reference layers 10L with the magnetization 90L in the second direction are arranged.

In the MTJ elements of regions RGL, RGR which neighbor in a direction (oblique direction of the cell array) crossing the X direction and Y direction in the X-Y plane, the directions of magnetization 90L, 90R of reference layers 10L, 10R are identical to each other.

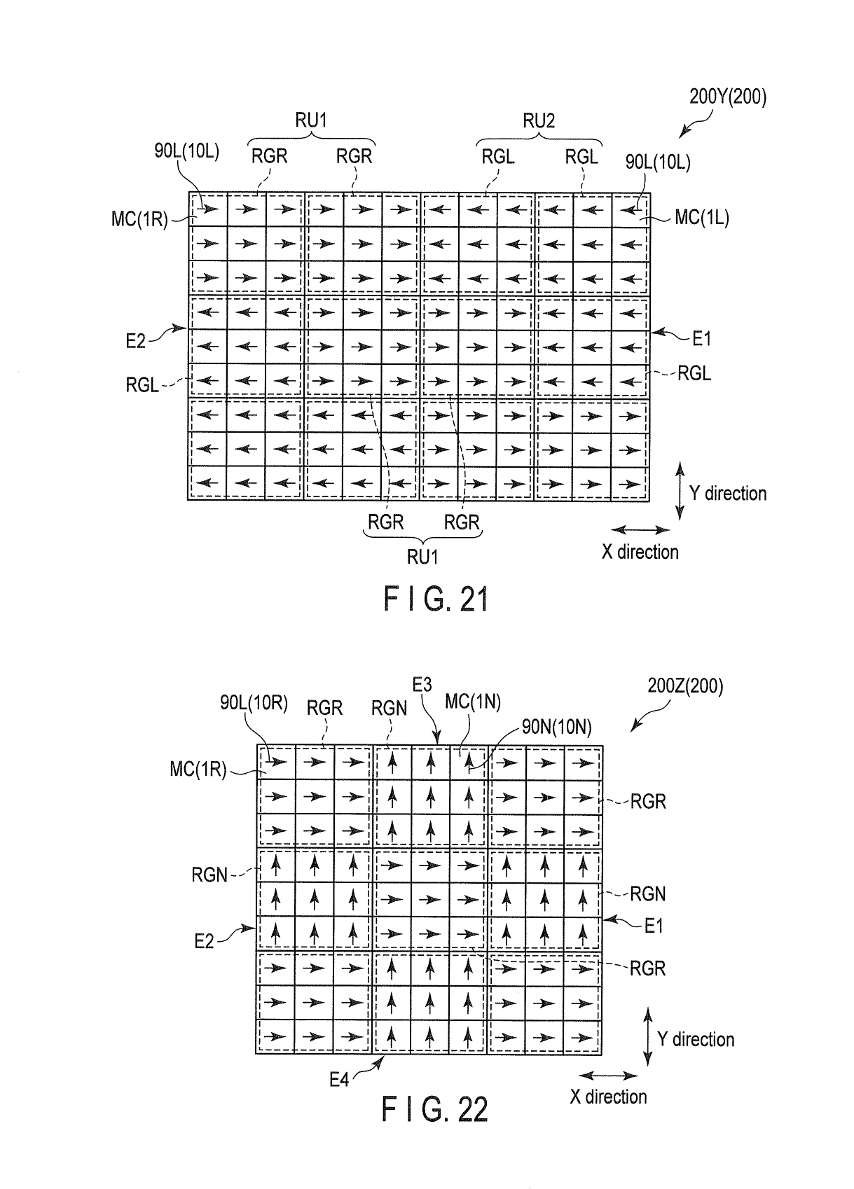

FIG. 21 is a schematic view for describing the layout of reference layers of MTJ elements in the cell array of an MRAM according to a modification of the second embodiment.

In a cell array 200Y of the MRAM of FIG. 21, the cell array 200Y with a pair pattern layout is formed in units of the region RGL, RGR which is set in the cell array 200Y.

Two regions RGR (RGL) neighboring in the X direction form one pair RU1 (RU2). In two pairs RU1, RU2 which neighbor in the X direction, the direction of magnetization 90L of reference layers 10L of plural MTJ elements 1L in one pair RU1 is opposite to the direction of magnetization 90R of reference layers 10R of plural MTJ elements 1R in the other pair RU2.

In each pair RU1, RU2, the directions of magnetization of reference layers 10L, 10R of MTJ elements 1L, 1R in the regions RGR, RGL are identical.

The pair pattern layout is formed by plural pairs RU1, RU2 each including two regions RGL, RGR including MTJ elements 1L, 1R having the reference layers 10L, 10R with the same direction of magnetization 90L, 90R, like the pairs formed in units of memory cells (e.g. two memory cells) as described with reference to FIG. 14 and FIG. 15.

Incidentally, the numbers of MTJ elements (memory cells) included in the respective regions RGR, RGL and in the respective pairs RU1, RU2 are equal.

FIG. 22 is a schematic view for describing the layout of reference layers of MTJ elements in the cell array of an MRAM according to a modification of the third embodiment.

As illustrated in FIG. 22, in mutually neighboring regions RGR, RGN in a cell array 200Z, the direction of magnetic anisotropy of reference layers 10R of plural MTJ elements 1R in the region RGR crosses the direction of magnetic anisotropy of reference layers 10N of plural MTJ elements 1N in the region RGN.

In FIG. 22, the region RGR, in which MTJ elements 1R including reference layers 10R with the magnetization direction toward the first side E1 are provided, neighbors in the X direction and Y direction the regions RLN in which MTJ elements 1N including reference layers 10N with the magnetization direction toward the third side E3 are provided. The direction parallel to the third side E3 of the cell array 200Z crosses the direction parallel to the first side E1 of the cell array 200Z.

In FIG. 20 to FIG. 22, each region RGR, RGL, RGN in the cell array 200 of each modification is a region of a matrix of 3×3. However, if the numbers of MTJ elements included in mutually neighboring regions are equal, each region may be a region of 2×2, a region of 4×4, or a region of 16×16.

In FIG. 20 and FIG. 21, MRAMs in which in-plane magnetization-type MTJ elements are used have been described. However, in the modifications, vertical magnetization-type MTJ elements may be used.

As in the modifications shown in FIG. 20 to FIG. 22, the directions of magnetization of reference layers in the regions neighboring in the X direction and Y direction are different from each other in units of plural regions set in the cell array. Thereby, like the arrangement patterns of reference layers in the cell arrays described in the first to third embodiments, the magnetic interference between the memory cells and between the MTJ elements in the cell array 200 can be reduced.

In addition, according to the modifications, MTJ elements with different magnetization directions can be relatively easily formed in the cell array.

Therefore, with the magnetic memories of the modifications of the embodiments, like the first to third embodiments, the reliability of the magnetic memory can be improved.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A magnetic memory comprising:
a cell array on a substrate; and
one or more first magnetoresistive effect elements and one or more second magnetoresistive effect elements, which are provided in the cell array, each of the first and second magnetoresistive effect elements including a first magnetic layer with an invariable direction of magnetization, a second magnetic layer with a variable direction of magnetization, and a nonmagnetic layer between the first magnetic layer and the second magnetic layer,
wherein at least one of the first magnetoresistive effect elements neighbors at least one of the second magnetoresistive effect elements in a first direction, and
directions of magnetization of the first magnetic layers of the first and second magnetoresistive effect elements, which neighbor in the first direction, are different from each other.

2. The magnetic memory according to claim 1, wherein the first magnetic layer has a magnetic anisotropy parallel to a surface of the substrate,
the magnetization of the first magnetic layer of the first magnetoresistive effect element is directed toward a first side in the first direction, and
the magnetization of the first magnetic layer of the second magnetoresistive effect element is directed toward a second side which is opposite to the first side in the first direction.

3. The magnetic memory according to claim 1, wherein the first magnetic layer of the first magnetoresistive effect element has a magnetic anisotropy parallel to a surface of the substrate in the first direction, and
the first magnetic layer of the second magnetoresistive effect element has a magnetic anisotropy parallel to the surface of the substrate in a second direction crossing the first direction.

4. The magnetic memory according to claim 3, wherein the first magnetoresistive effect element has a plan-view shape with a longitudinal direction of an element pattern in the first direction, and
the second magnetoresistive effect element has a plan-view shape with a longitudinal direction of an element pattern in the second direction.

5. The magnetic memory according to claim 1, wherein the first magnetic layer has a magnetic anisotropy perpendicular to a surface of the substrate,
the magnetization of the first magnetic layer of the first magnetoresistive effect element is directed toward a substrate side, and
the magnetization of the first magnetic layer of the second magnetoresistive effect element is directed toward a side opposite to the substrate side.

6. The magnetic memory according to claim 1, wherein a plurality of the first magnetoresistive effect elements, which are arranged in the first direction, form a first unit,
a plurality of the second magnetoresistive effect elements, which are arranged in the first direction, form a second unit,
the first unit neighbors the second unit in the first direction,
the directions of magnetization of the first magnetic layers of the plurality of first magnetoresistive effect elements in the first unit are identical to each other,
the directions of magnetization of the first magnetic layers of the plurality of second magnetoresistive effect elements in the second unit are identical to each other, and
the directions of magnetization of the first magnetic layers of the plurality of first magnetoresistive effect elements in the first unit are opposite to the directions of magnetization of the first magnetic layers of the plurality of second magnetoresistive effect elements in the second unit.

7. The magnetic memory according to claim 1, wherein the cell array includes a first region including a plurality of the first magnetoresistive effect elements, and a second region including a plurality of the second magnetoresistive effect elements,
the first region neighbors the second region in the first direction,
the directions of magnetization of the first magnetic layers of the plurality of first magnetoresistive effect elements in the first region are identical to each other,
the directions of magnetization of the first magnetic layers of the plurality of second magnetoresistive effect elements in the second region are identical to each other, and
the directions of magnetization of the first magnetic layers of the plurality of first magnetoresistive effect elements in the first region are different from the directions of magnetization of the first magnetic layers of the plurality of second magnetoresistive effect elements in the second region.

8. The magnetic memory according to claim 1, further comprising:
a third magnetoresistive effect element which neighbors the second magnetoresistive effect element in a second direction crossing the first direction in the cell array; and
a fourth magnetoresistive effect element which neighbors the first magnetoresistive effect element in the second direction in the cell array,
wherein each of the third and fourth magnetoresistive effect elements includes the first magnetic layer, the second magnetic layer and the nonmagnetic layer,
the directions of magnetization of the first magnetic layer of the third magnetoresistive effect element are identical to the directions of magnetization of the first magnetic layer of the first magnetoresistive effect element, and are different from the directions of magnetization of the first magnetic layer of the second magnetoresistive effect element, and
the directions of magnetization of the first magnetic layer of the fourth magnetoresistive effect element are different from the directions of magnetization of the first magnetic layer of the first magnetoresistive effect element, and are identical to the directions of magnetization of the first magnetic layer of the second magnetoresistive effect element.

9. The magnetic memory according to claim 8, wherein the first magnetic layer has a magnetic anisotropy parallel to a surface of the substrate,
the magnetization of the first magnetic layers of the first and third magnetoresistive effect elements is directed toward a first side in the first direction, and
the magnetization of the first magnetic layers of the second and fourth magnetoresistive effect elements is directed toward a second side which is opposite to the first side in the first direction.

10. The magnetic memory according to claim 8, wherein the first magnetic layer has a magnetic anisotropy perpendicular to a surface of the substrate,
the magnetization of the first magnetic layers of the first and third magnetoresistive effect elements is directed toward a substrate side, and
the magnetization of the first magnetic layers of the second and fourth magnetoresistive effect elements is directed toward a side opposite to the substrate side.

11. A magnetic memory comprising:
a cell array on a substrate;
a first unit including a plurality of first magnetoresistive effect elements arranged in a first direction in the cell array; and
a second unit including a plurality of second magnetoresistive effect elements arranged in the first direction in the cell array,
each of the plurality of first and second magnetoresistive effect elements including a first magnetic layer with an invariable direction of magnetization, a second magnetic layer with a variable direction of magnetization, and a nonmagnetic layer between the first magnetic layer and the second magnetic layer, and directions of magnetization of the first magnetic layers of the first and second magnetoresistive effect elements being different from each other.

12. The magnetic memory according to claim 11, wherein the directions of magnetization of the first magnetic layers of the plurality of first magnetoresistive effect elements in the first unit are identical to each other, and
the directions of magnetization of the first magnetic layers of the plurality of second magnetoresistive effect elements in the second unit are identical to each other.

13. The magnetic memory according to claim 11, wherein the first magnetic layer has a magnetic anisotropy parallel to a surface of the substrate,
the magnetization of the first magnetic layers of the first magnetoresistive effect elements is directed toward a first side in the first direction, and
the magnetization of the first magnetic layers of the second magnetoresistive effect elements is directed toward a second side which is opposite to the first side in the first direction.

14. The magnetic memory according to claim 11, wherein the first magnetic layer has a magnetic anisotropy perpendicular to a surface of the substrate,
the magnetization of the first magnetic layers of the first magnetoresistive effect elements is directed toward a substrate side, and
the magnetization of the first magnetic layers of the second magnetoresistive effect elements is directed toward a side opposite to the substrate side.

15. The magnetic memory according to claim 11, further comprising:
a third unit neighboring the first unit in a third direction which is an oblique direction to the first and second directions, and neighboring the second unit in a fourth direction which is an oblique direction to the first and second directions and crosses the third direction, the third unit including a plurality of third magnetoresistive effect elements arranged in the first direction,
wherein each of the plurality of third magnetoresistive effect elements includes the first magnetic layer, the second magnetic layer and the nonmagnetic layer,
the directions of magnetization of the first magnetic layers of the plurality of third magnetoresistive effect elements are identical to the directions of magnetization of the first magnetic layers of the first magnetoresistive effect elements, and
the directions of magnetization of the first magnetic layers of the plurality of third magnetoresistive effect elements is opposite to the directions of magnetization of the first magnetic layers of the second magnetoresistive effect elements.

16. The magnetic memory according to claim 15, wherein the first magnetic layer has a magnetic anisotropy parallel to a surface of the substrate,
the directions of magnetization of the first magnetic layers of the plurality of first and third magnetoresistive effect elements are directed toward a first side in the first direction, and
the directions of magnetization of the first magnetic layers of the plurality of second magnetoresistive effect elements are directed toward a second side in the first direction.

17. The magnetic memory according to claim 15, wherein the first magnetic layer has a magnetic anisotropy perpendicular to a surface of the substrate,
the directions of magnetization of the first magnetic layers of the plurality of first and third magnetoresistive effect elements are directed toward a substrate side, and
the directions of magnetization of the first magnetic layers of the plurality of second magnetoresistive effect elements are directed toward a side opposite to the substrate side.

18. A magnetic memory comprising:
a cell array on a substrate;
one or more first and one or more second regions in the cell array;
a plurality of first magnetoresistive effect elements in the first region and a plurality of second magnetoresistive effect elements in the second region, each of the first and second magnetoresistive effect elements including a first magnetic layer with an invariable direction of magnetization, a second magnetic layer with a variable direction of magnetization, and a nonmagnetic layer between the first magnetic layer and the second magnetic layer, directions of magnetization of the first magnetic layers of the plurality of first magnetoresistive effect elements being identical to each other, directions of magnetization of the first magnetic layers of the plurality of second magnetoresistive effect elements being identical to each other, and the directions of magnetization of the first magnetic layers of the plurality of first magnetoresistive effect elements being different from the directions of magnetization of the first magnetic layers of the plurality of second magnetoresistive effect elements.

19. The magnetic memory according to claim 18, further comprising:
a third region in the cell array; and
a plurality of third magnetoresistive effect elements in the third region, each of the third magnetoresistive effect elements including the first magnetic layer, the second magnetic layer and the nonmagnetic layer,
wherein the directions of magnetization of the first magnetic layers of the plurality of third magnetoresistive effect elements are identical to each other,
the directions of magnetization of the first magnetic layers of the plurality of third magnetoresistive effect elements are identical to the directions of magnetization of the first magnetic layers of the plurality of first magnetoresistive effect elements, and
the directions of magnetization of the first magnetic layers of the plurality of third magnetoresistive effect elements are different from the directions of magnetization of the first magnetic layers of the plurality of second magnetoresistive effect elements.

20. The magnetic memory according to claim 18, wherein a plurality of the first regions arranged in the first direction form a first unit, a plurality of the second regions arranged in the first direction form a second unit, and
the first and second units are arranged in the first direction.
